(19) United States
(12) Patent Application Publication
(10) Pub. No.: US 2008/0179721 A1
(43) Pub. Date: Jul. 31, 2008

(54) STACKING OF TRANSFER CARRIERS WITH APERTURE ARRAYS AS INTERCONNECTION JOINTS

(76) Inventor: Cheng-Lien Chiang, Taipei (TW)

Correspondence Address: PAI PATENT & TRADEMARK LAW FIRM, 1001 FOURTH AVENUE, SUITE 3200, SEATTLE, WA, 98154, US

(21) Appl. No.: 11/669,880

(22) Filed: Jan. 31, 2007

(51) Int. Cl. H01L 23/495; H01L 23/48

(52) U.S. Cl. 257/666; 257/773; 257/686; 257/E23.01; 257/E23.031

(57) ABSTRACT

A transfer carrier comprising a transfer substrate, two aperture arrays, a contact pattern and a semiconductor device. The transfer substrate located on the opposed sides of the transfer substrate to define a cavity on the transfer substrate, the aperture arrays has a top surface and a bottom surface. The two aperture arrays have apertures extending from the top surface through to the bottom surface. The apertures have conductive layers formed on the inner surfaces of the apertures. The contact pattern is located with contacts lo electrically connected to the corresponding conductive layer of the apertures. The semiconductor device has pads arranged in identical pattern as the contact pattern, the semiconductor device being electrically connected to the contacts. The transfer carrier is also manufactured as an integrated circuit package. The transfer carriers and integrated circuit packages are stacked via solder connections.

### BACKGROUND

1. Field of Invention

The present invention relates to a stacking of transfer carriers. More particularly, the present invention relates to a stacking of transfer carriers with aperture arrays as interconnection joints.

2. Description of Related Art

Various techniques of chip stacking have developed over the years to stack integrated circuit packages in a compact and low profile manner. In stacking fine-pitch ball grid array (FBGA) packages, a transfer substrate acting as a supporting plate and provides interconnection between the FBGA packages is used to transfer the electrical signal. The integrated circuit package is electrically connected to the conductive patterns of the transfer substrate arranged in the same pattern as the package pin configuration via solder balls. The transfer substrate also has pad arrays disposed near the edges of the substrate to make connection with other transfer substrates. The conductive patterns and pad arrays are metal layers formed on both sides of the transfer substrate and are connected with their counter part on the opposite side by metal via.

The manufacturing of transfer substrates with pads as interconnection joints adds complexity to the interconnect substrate with additional metal via needed to connect corresponding pads on both sides of the substrate. Also, with the pads as interconnection joints, these are no variations of how the interconnection joints can be connected. The pads may only be soldered together via solder balls. Therefore a new interconnection joint structure is needed to simplify the manufacturing process and also provides variation in joining the interconnection joints.

### SUMMARY

The present invention is directed to a transfer carrier that it satisfy this need of a new interconnection joint. The transfer carrier comprises a transfer substrate, two aperture arrays, a conductive pattern, and a semiconductor device. The semiconductor device may be an integrated circuit package or a bare die. When the semiconductor device is an integrated circuit package, such as a FBGA packaged memory chip, it is connected to the transfer substrate by making a solder connection with the conductive pattern. The conductive pattern may be apertures with conductive plating around the rim of the apertures on the bottom surface of the transfer substrate. Solder paste may be applied filling the apertures. The conductive plating is on each aperture of the conductive pattern is electrically connected to the corresponding apertures of the two aperture arrays. The two aperture arrays located on the opposite sides of the transfer substrate defining a cavity, the aperture arrays have conductive layers, such as conductive plating, on the inner side of the apertures extending from the top surface to the bottom surface of the substrate. The semiconductor device is placed in the cavity so that the thickness of the device does not exceed the height of the sidewall of the cavity. The conductive plating may further extend onto the top and bottom surface of the substrate around the rim of the apertures. The conductive layers provide electric conduction from the top surface to the bottom surface of the transfer substrate. By using apertures as interconnection joints, it eliminated the need for disposing top and bottom surface pads and the connecting metal via. The connection between the top and bottom surface in the present invention is through a simple puncture and a single plating process. The transfer carriers may be stacked by planting conductive contacts in the aperture or making connections around the rims of the aperture providing a hollow connection joint.

When the semiconductor device is a bare die, the conductive pattern may be pads disposed on the bottom surface of the transfer substrate making a bond wire connection with the bond pads on the bare die. An epoxy layer fills the cavity encapsulating the bare die to complete the package.

The aperture interconnection joint structure may also be applied to the molding of a new integrated circuit package. Instead of using a transfer carrier, the aperture arrays are formed as leads of a leadframe package of a bare die. The lead frame package is encapsulated by a molding compound with pads disposed thereon and exposing the leads.

The integrated circuit package may be stacked in the same manner as the transfer carrier while each integrated circuit package is smaller in size than the transfer carrier.

The present invention provides a transfer carrier with aperture arrays as interconnection joints. Using apertures as interconnection joints simplifies the transfer substrate manufacturing process and also provides variation in joining the interconnection joints.

It is to be understood that both the foregoing general description and the following detailed description are by examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 is a top, bottom and side view of the transfer carrier according to the first embodiment of the present invention;

FIG. 2A is a cross section view of one plating option according to the first embodiment of the present invention;

FIG. 2B is a cross section view of one plating option according to the first embodiment of the present invention;

FIG. 2C is a cross section view of one plating option according to the first embodiment of the present invention;

FIG. 2D is a cross section view of one plating option according to the first embodiment of the present invention;

FIG. 3A is a diagram of the second embodiment of the present invention;

FIG. 3B is a bottom view according to the second embodiment of the present invention;

FIG. 3C is a top view according to the second embodiment of the present invention;

FIG. 4 is a side view of the stacking module;

FIG. 5A is a cross section view of one interconnection option of the interconnection joint;

FIG. 5B is a cross section view of one interconnection option of the interconnection joint;

FIG. 5C is a cross section view of one interconnection option of the interconnection joint;

FIG. 6A is a diagram of the integrated circuit package according to the third embodiment of the present invention;

FIG. 6B is a transparent side view of the integrated circuit package according to the third embodiment of the present invention;

FIG. 6C is a diagram of the integrated circuit package according to the third embodiment of the present invention;

FIG. 7A is a cross section view of one stacking option of the integrated circuit packages;

FIG. 7B is a cross section view of one stacking option of the integrated circuit packages; and

FIG. 7C is a cross section view of one stacking option of the integrated circuit packages.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

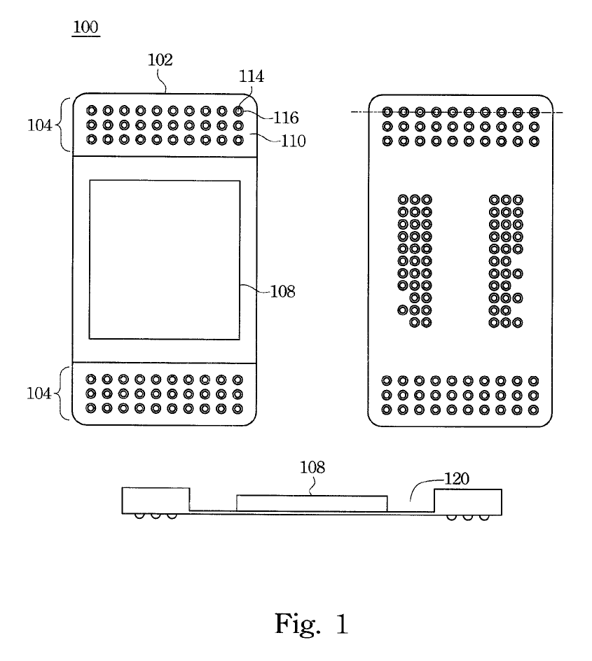

Please refer to FIG. 1, a top, bottom and side view of the transfer carrier according to the first embodiment of the present invention. The transfer carrier 100 includes a transfer substrate 102, two aperture arrays 104, a conductive pattern 106, and a semiconductor device 108. The transfer substrate defines a top surface 110 and a bottom surface 112. The two aperture arrays 104 have apertures 114 extending from the top surface 110 through to the bottom surface 112. The two aperture arrays 104 are located on the opposite sides of the lo transfer substrate 102 and defining a cavity 120. The cavity 120 allows the thickness of semiconductor device 108 to be not higher than the depths of the cavity 120, creating a stackable structure. The apertures 114 have conductive plating 116 formed in the aperture. The conductive plating 116 is a plated through hole (PTH) plating using a metal such as gold, silver, tin, tin-lead alloy, copper alloy, aluminum, or the combination thereof. The contact pattern 106 is located between the two aperture arrays 104. The contact pattern 106 is composed of contacts 118 extending from the top surface 110 through to the bottom surface 112, the contacts 118 are electrically connected to the corresponding conductive plating 116 of the apertures 114. The contacts 118 are apertures having conductive plating 116 around the rim of the apertures on the bottom surface 112. Finally, the semiconductor device 108, which has pads (not shown) arranged in identical pattern as the contact pattern 106, is electrically connected to the contacts 118. Therefore, by accessing the conductive plating on the two aperture arrays 104, one has access to the semiconductor device.

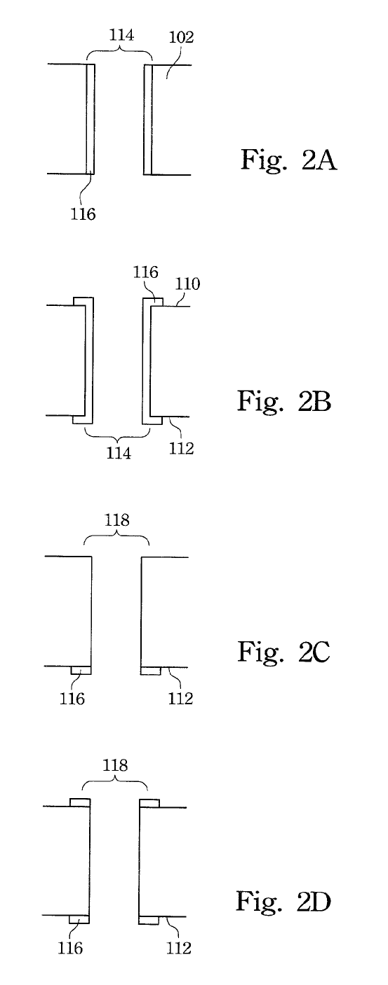

Referring to FIG. 2A, 2B, 2C, and 2D simultaneously, cross section views of plating options along the line AB of an aperture in FIG. 1. In FIG. 2A, the conductive plating 116 covers the inner surface of the apertures 114. In FIG. 2B, the conductive plating 116 extends onto the top surface 110 and bottom surface 112. In FIG. 2C, the cross section view of a contact 118, the conductive plating 116 is formed on the bottom surface 112 around the rim of the contact 118. In FIG. 2D, the conductive plating 116 is formed on the top surface 110 and the bottom surface 112 around the rim of the contact 118.

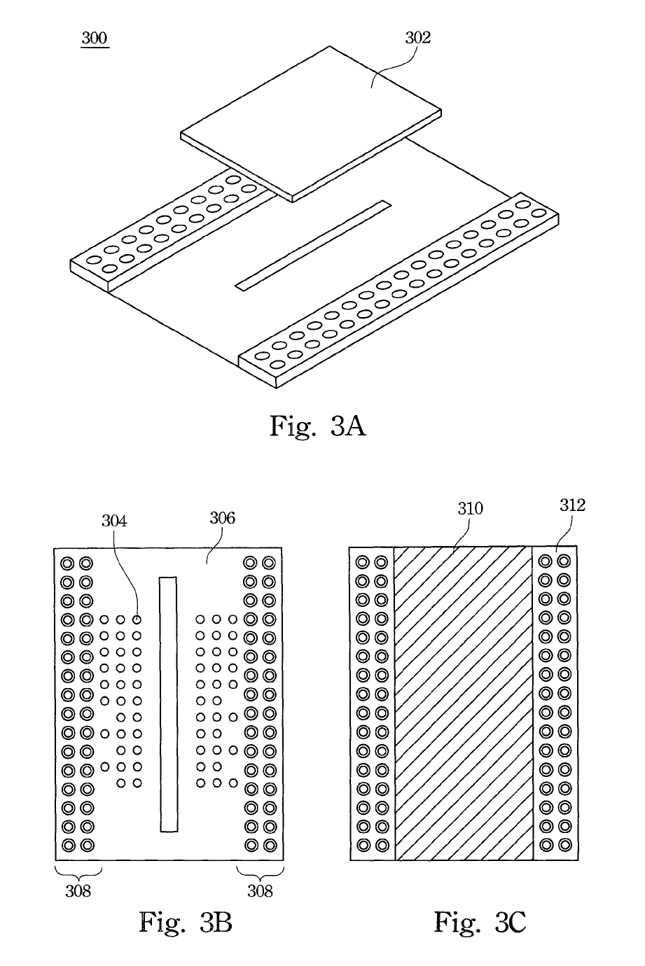

Please refer to FIG. 3A, 3B and 3C simultaneously, diagrams of the lo second embodiment of the present invention. In FIG. 3A, the transfer carrier 300 has the same structure as the transfer carrier 100, except that the semiconductor device is an unpackaged bare die 302. The bare die 302 may be a DRAM die, a NOR flash die, a NAND flash die, or a MRAM die. The bare die 302 has bond pads (not shown) electrically connected through bond wires (not shown) with the contacts 304 on the bottom surface 306 shown in FIG. 3B. The contacts 304 are conductive pads with flat metal surfaces. The contacts 304 are electrically connected to the two aperture arrays 308 to provide stackable access to the bare die 302. In FIG. 3C, an epoxy layer 310 is applied filling the cavity on the top surface 312 to provide protection for the bare die 302.

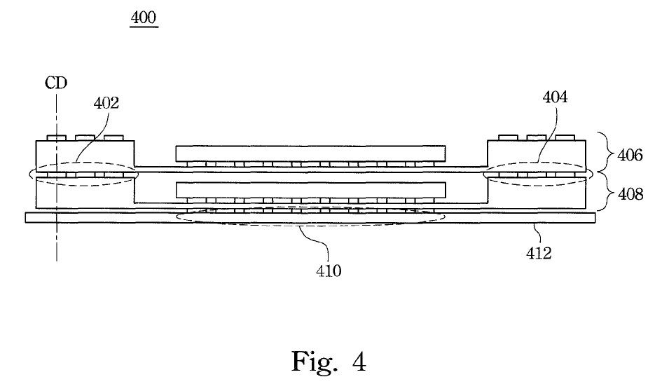

Please refer to FIG. 4, a side view of the stacked module 400 of the transfer carriers 100 described above. A conductive contact is applied at the interconnection joints 402 and 404 to secure connection between the transfer carrier 406 and transfer carrier 408. The conductive contacts are also applied to the interconnection joints 410 to secure connection between the transfer carriers 406, 408 and the printed circuit board 412. The conductive contact may be an electrically conductive adhesive contact, a mechanically structured contact, or a combined application of the electrically conductive adhesive contact and the mechanically structured contact.

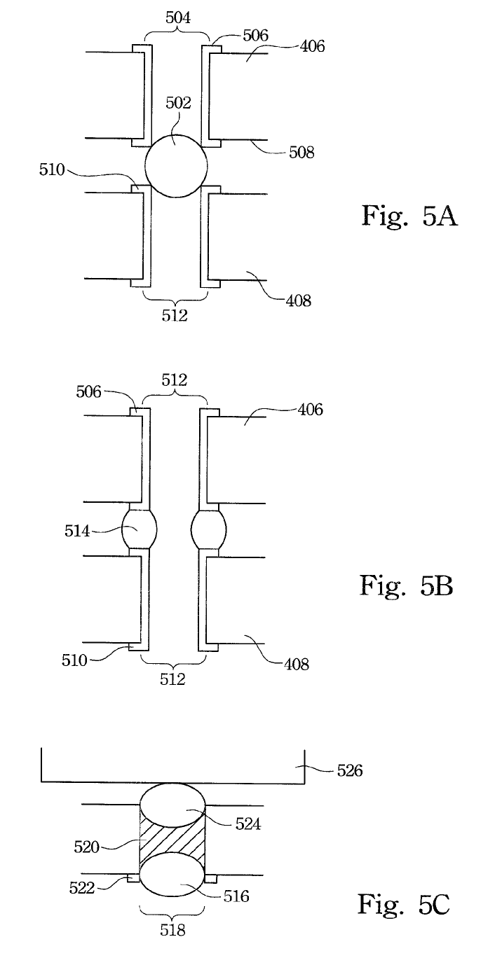

Please refer to FIG. 5A, 5B, and 5C simultaneously, cross section diagrams of interconnection options applied to the interconnection joints 402, 404, and 410 along the line CD. In FIG. 5A, a conductive contact 502 is planted into the aperture 504 making contact with the conductive plating 506 and protruding out of the bottom surface 508 of the transfer carrier 406. The lo conductive contact 502 is then connected with the corresponding conductive plating 510 of the aperture 512 on the transfer carrier 408. In FIG. 5B, a conductive contact 514 is applied on around the rim of the aperture 504 making contact with the conductive plating 506. The conductive contact 514 is then soldered onto the corresponding conductive plating 510 of the aperture 512 on the transfer carrier 408. In FIG. 5C, the interconnection option of interconnection joint 410, a conductive contact 516 is planted into the aperture 518 and solder paste 520 fills the apertures 518 providing electrical conduction between the conductive contact 516 and the conductive plating 522. The solder ball 524 on the pads of the semiconductor device 526 is inserted into the aperture 518 making electrical connection with the conductive plating 522 and the conductive contact 516. The conductive contact 502, 514, and 516 may be a solder ball, a solder plated copper ball, a solder plated epoxy ball, a solder plated rubber ball, a solder plated rosin ball, a metal ball or an alloy ball. The transfer carrier 300 in FIG. 3a, 3b, and 3c may be stacked the same way as described above, and therefore no additional explanation is provided here.

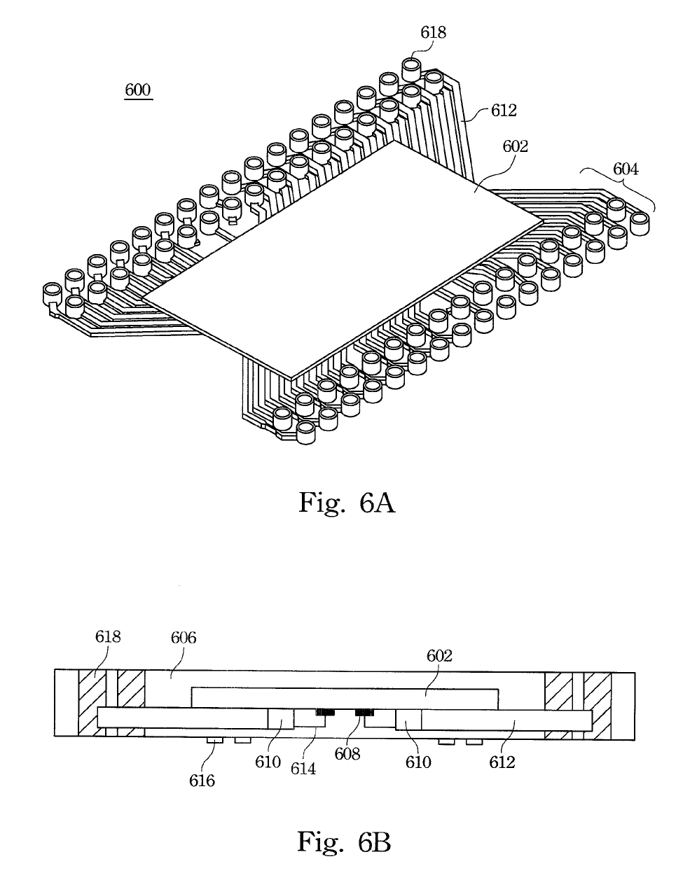

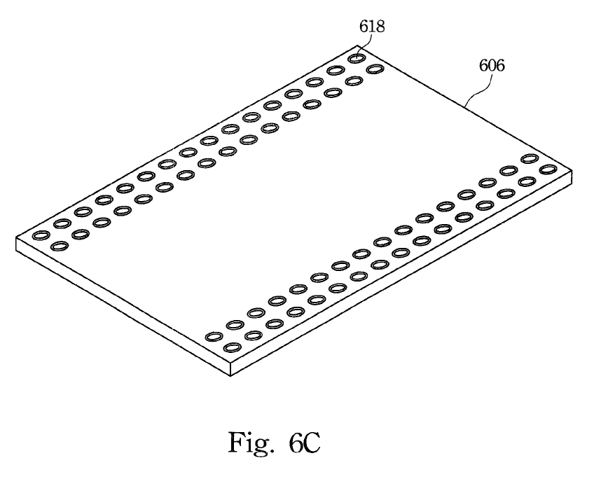

Please refer to FIG. 6A, 6B, and 6C simultaneously, diagrams of the third embodiment according to the present invention. In this embodiment, FIG. 6A shows the integrated circuit package 600 includes a semiconductor die 602 and a leadframe 604. In FIG. 6B, a transparent side view of the third embodiment, the semiconductor die 602, such as a DRAM die, a NOR flash die, a NAND flash die, or a MRAM die having bond pads 608 electrically connected to a first end 610 of the lead fingers 612 via bond wires 614. The bond wires (not shown) also connect the bond pads 608 to the conductive pads 616 disposed on the molding compound 606. The second end of the lead fingers 612 lo extends and makes electrical connection with the outer surface of the leads 618 of the leadframe 604. The leads 618 are formed in a hollow cylindrical shape arranged in two arrays providing access to the bond pads 608. In FIG. 6C, the molding compound 606, such as epoxy, encapsulates the semiconductor die 602, the bond wires 614, the lead fingers 612 and the outer surface of the leads 618 completing the integrated circuit package 600. The leads 618 are kept hollow at the center, forming apertures similar to the apertures of the first and second embodiments. The leadframe 604 is made of a copper based alloy material or an alloy-42 material.

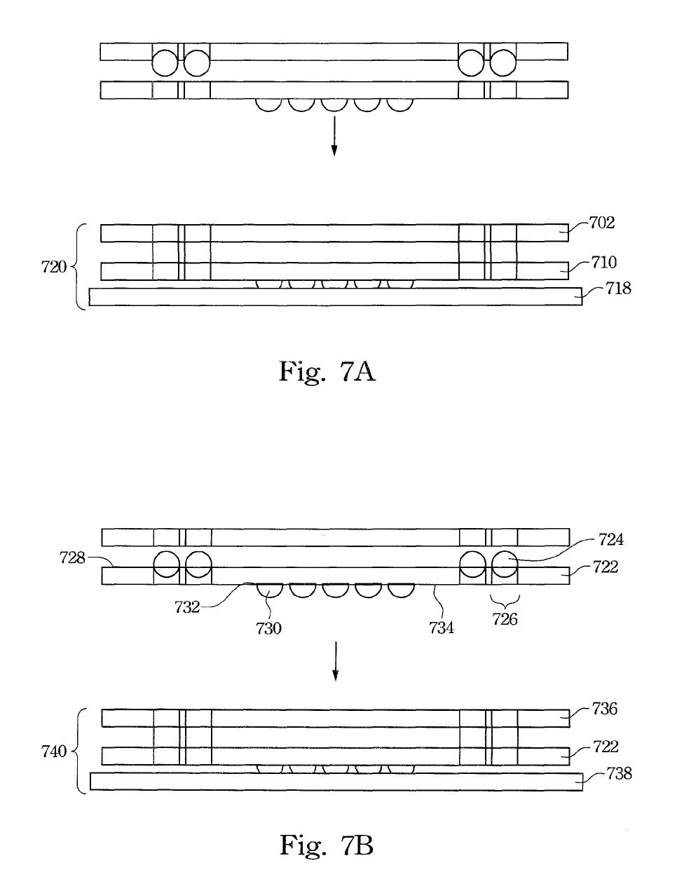

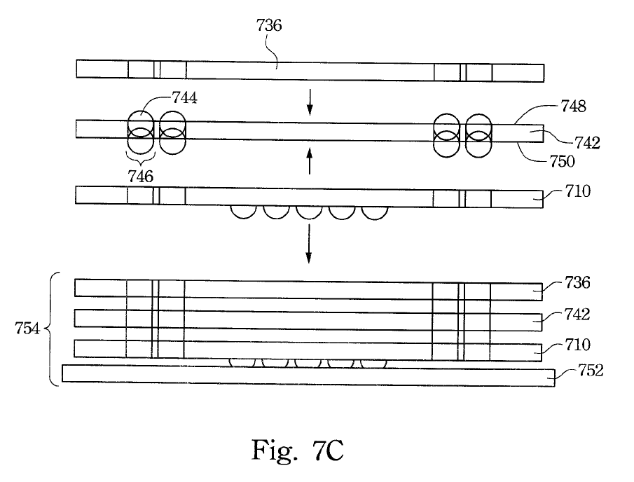

Please refer to FIG. 7A, 7B, and 7C, diagrams of stacking options of the integrated circuit packages 600. In FIG. 7A, integrated circuit package 702 has solder balls 704 planted into the aperture 706, protruding out of the bottom surface 708. The integrated circuit package 710 has solder balls 712 attached to the conductive pads 714 and protruding out of the bottom surface 716. The integrated circuit packages 702 and 710 may be stacked onto a printed circuit board 718 to form a stacking module 720. In FIG. 7B, integrated circuit package 722 has solder balls 724 planted into the aperture 726 and protruding out of the top surface 728. The integrated circuit package 722 also has solder balls 730 attached to the conductive pads 732 and protruding out of the bottom surface 734. The integrated circuit package 722 and 736 are stacked onto a printed circuit board 738 to form a stacking module 740. Lastly, in FIG. 7C, integrated circuit 742 has solder balls 744 planted into the aperture 746 and protruding out of the top surface 748 and bottom surface 750. The integrated circuit packages 736, 742 and 710 are stacked onto a printed circuit board 752 to form a stacking module 754.

The embodiments according to the present invention provide a transfer carrier with apertures as interconnection joints. The transfer carrier may be packaged chips attached to a transfer substrate, a bare die attached to a transfer substrate, or a semiconductor die molded as a transfer carrier. The aperture interconnection joints are easier to manufacture than conductive pads and provides a more solid conductive path from the top surface of the transfer carrier to the bottom surface of the transfer carrier. Also, the aperture allows variation in soldering together the interconnection joints as described in the above soldering options. The variation will be advantageous in future stacking applications of transfer carriers.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A transfer carrier comprising:
a transfer substrate defining a top surface and a bottom surface; two aperture arrays located on the opposed sides of the transfer substrate to define a cavity on the transfer substrate, the aperture arrays having a plurality of first apertures extending from the top surface through to the bottom surface, at least one conductive layer forming in the aperture;
a contact pattern located on the transfer substrate with contacts lo electrically connected to the corresponding conductive layer of the apertures; and
a semiconductor device having a plurality of pads arranged in identical pattern as the contact pattern, the semiconductor device being electrically connected to the contacts.

2. The transfer carrier of claim 1, wherein the conductive layer is formed by a through hole plating (PTH) of a conductive material.

3. The transfer carrier of claim 2, wherein the conductive material is gold, silver, tin, tin-lead alloy, copper alloy, aluminum or a combination thereof.

4. The transfer carrier of claim 2, wherein the through hole plating is formed on the inner surface of the first aperture.

5. The transfer carrier of claim 4, wherein the through hole plating further extends around the rim of the aperture array onto the top surface and the bottom surface.

6. The transfer carrier of claim 1, wherein the contacts are a plurality of second apertures having a conductive layer formed around the rim of the apertures on the top surface, the bottom surface or both surfaces.

7. The transfer carrier of claim 6, further comprising a solder paste filling lo the second apertures.

8. The transfer carrier of claim 1, wherein the contacts are a plurality of conductive pads.

9. The transfer carrier of claim 1, wherein the semiconductor device is a fine-pitch ball grid array (FBGA) package.

10. The transfer carrier of claim 1, wherein the semiconductor device is a bare die.

11. The transfer carrier of claim 9, wherein the FBGA package being electrically connected to the contacts via a solder ball.

12. The transfer carrier of claim 10, wherein the bare die being electrically connected to the contacts via a wire bond.

13. The transfer carrier of claim 12, the transfer carrier further comprising an epoxy layer filling the cavity and encapsulation the bare die.

14. A stacking module, comprising:
a top transfer carrier, comprising:
a first transfer substrate defining a first surface and a second surface;
a first set of two aperture arrays located on the opposed sides of the first transfer substrate to define a first cavity on the transfer substrate, the first set of two aperture arrays having a plurality of first apertures extending from the first surface through to the second surface, the first apertures having at least one first conductive layer forming in the first apertures;
a first contact pattern located on the first transfer substrate with first contacts electrically connected to the corresponding conductive layer of the apertures; and
a first semiconductor device having a plurality of first pads arranged in identical pattern as the first contact pattern, the semiconductor device being electrically connected to the contact pattern;
a bottom transfer carrier, comprising:
a second transfer substrate defining a third surface and a fourth surface;
a second set of two aperture arrays located on the opposed sides of the second transfer substrate to define a second cavity on the second transfer substrate, the second set of two aperture arrays having a plurality of second apertures extending from the third surface through to the fourth surface, the second apertures having at least one second conductive layer forming in the second aperture;
a second contact pattern located on the second transfer substrate with second contacts electrically connected to the corresponding second conductive layer of the second apertures; and
a second semiconductor device having a plurality of second pads arranged in identical pattern as the second contact pattern, the second semiconductor device being electrically connected to the contact pattern; and
a plurality of conductive contacts electrically connecting the first conductive layers of the first set of aperture arrays and the second conductive layers of the second set of aperture arrays.

15. The stacking module of claim 14, wherein the conductive contacts are an electrically conducting adhesive contact, a mechanically structured contact, or a combination thereof.

16. The stacking module of claim 15, wherein the electrically conducting adhesive contacts are made from a material selected from the group consisting of a solder ball, a solder plated copper ball, a solder plated epoxy ball, a solder plated rubber ball, a solder plated rosin ball, a metal ball and an alloy ball.

17. The stacking module of claim 14, wherein the conductive contacts are planting into the first apertures.

18. The stacking module of claim 14, wherein the conductive contact is formed around the rim of the first apertures.

19. An integrated circuit package, comprising:
a semiconductor die having a plurality of bond pads;
a leadframe comprising:
a plurality of lead fingers having a first end and a second end, the first end electrically connected to the bond pad by a bond wire; and
a plurality of leads with a hollow cylindrical shape having an outer surface and an inner surface, the leads electrically connecting to the second end of the corresponding lead fingers; and
a molding compound having a plurality of pads disposed thereon, the pads electrically connecting to the corresponding bond pads via the bond wire, the molding compound encapsulating the semiconductor die, the bond wires, the lead fingers, and the outer surface of the leads.

20. The integrated circuit package of claim 19, wherein the semiconductor die is a DRAM die, a NAND flash die, a NOR flash die, or a MRAM die.

21. The integrated circuit package of claim 19, wherein the leadframe is a copper based alloy material or an alloy-42 material.

22. A stacking module comprising:
a first integrated circuit package comprising:
a first semiconductor die having a plurality of first bond pads;
a first leadframe comprising:
a plurality of first lead fingers having a first end and a second end, the first end electrically connected to the first bond pad by a first bond wire; and
a plurality of first leads with a hollow cylindrical shape having a first outer surface, and a first inner surface, the first leads electrically connected to the second end of the corresponding first lead fingers; and
a first molding compound having a plurality of first pads disposed thereon, the first pads electrically connected to the corresponding first bond pads via the first bond wire, the first molding compound encapsulating the first semiconductor die, the first bond wires, the first lead fingers, and the first outer surface of the first leads;
a second integrated circuit package, comprising:
a second semiconductor die having a plurality of second bond pads;
a second leadframe comprising:
a plurality of second lead fingers having a third end and a fourth end, the third end electrically connected to the second bond pad by a second bond wire; and
a plurality of second leads with a hollow cylindrical shape having a second outer surface, and a second inner surface, the second leads electrically connected to the fourth end of the corresponding second lead fingers;
a second molding compound having a plurality of second pads disposed thereon, wherein the second pads electrically connected to the corresponding second bond pads via the second bond wire, the second molding compound encapsulating the second semiconductor die, the second bond wires, the second lead fingers, and the second outer surface of the second leads; and
a plurality of conductive contacts electrically connecting the first leads of the first leadframe and the second leads of the second leadframe.

23. The stacking module of claim 22, wherein the conductive contacts are a conductive adhesive contact, a mechanically structured contact, or a combination thereof.

24. The stacking module of claim 22, wherein the conductive adhesive contacts are made from a material selected from the group consisting of a solder ball, a solder plated copper ball, a solder plated epoxy ball, a solder plated rubber ball, a solder plated rosin ball, a metal ball and an alloy ball.

25. The stacking module of claim 22, wherein the conductive contact is a solder ball planting into the first leads.

26. The stacking module of claim 22, wherein the conductive contact is a solder material forming around the rim of the first leads.
